(19) United States
(12) Patent Application Publication
(10) Pub. No.: US 2008/0045041 A1
(43) Pub. Date: Feb. 21, 2008

(54) Liquid Immersion Laser Spike Anneal

(75) Inventor: Takashi Nakao, Naka-gun (JP)

Correspondence Address: BANNER & WITCOFF, LTD., 1100 13th STREET, N.W., SUITE 1200, WASHINGTON, DC, 20005-4051, US

(73) Assignee: TOSHIBA AMERICA ELECTRONIC COMPONENTS, INC., Irvine, CA (US)

(21) Appl. No.: 11/465,182

(22) Filed: Aug. 17, 2006

(51) Int. Cl. H01L 21/00

(52) U.S. Cl. 438/795

(57) ABSTRACT

A method and apparatus for laser annealing a semiconductor wafer comprises placing a semiconductor wafer in a liquid bath such that at least a portion of the wafer is immersed in the liquid. Laser light is directed through the liquid and onto a surface of the wafer to heat the surface for annealing. By selecting a liquid having a substantially greater heat capacity than that of the surrounding materials (silicon substrate, silicon oxide, metal silicide, etc.), the liquid functions as the primary heat sink for diffusing the heat of annealing. Temperature variations which occur during cooling as a result of differences in heat capacities of the surrounding materials are minimized.

### BACKGROUND OF THE INVENTION

During laser spike annealing in the manufacture of semiconductor wafers, thermal energy for annealing is provided by applying laser light to the surface of the wafer for very short time intervals, typically from several nanoseconds to several milliseconds. Heat energy from the laser light raises the temperature of the wafer surface for annealing. Following application of the laser light, the wafer surface cools in a relatively short period of time by diffusing heat energy to the underlying substrate.

Several techniques have been developed in efforts to achieve uniform heating during laser spike annealing. In one technique, light arc film is used to offset differences in light absorption coefficients between Si, SiO₂, and/or other materials present in the wafer. In another technique, very long wavelength laser light, such as CO₂ laser light with a wavelength of >10 μm, helps to reduce pattern density effects of laser light absorption.

As shown in FIG. 1A, a semiconductor wafer typically has more than one type of material below the surface, such as a silicon substrate and an oxide. In general, these different materials have different heat capacities (thermal conductivities). For example, silicon has a higher heat capacity than that of silicon oxide. When materials having different heat capacities are present, heat is transferred from the wafer surface to the underlying materials at different rates, leading to non-uniform temperatures across the wafer surface as the surface cools following laser annealing, as illustrated in FIG. 1B. Present laser annealing techniques do not account for temperature variations resulting from the different heat capacities of the underlying substrate materials.

There remains a need for improved techniques for achieving uniform heating during laser spike annealing. It would be particularly desirable to develop a technique that accounts for differences in heat capacities of materials which can lead to non-uniform temperatures as the surface cools immediately following application of laser light.

### SUMMARY OF THE INVENTION

One aspect of the present invention is directed to a method of laser annealing a semiconductor wafer. The method comprises placing a semiconductor wafer in a liquid bath such that at least a portion of the wafer is immersed in liquid. Laser light is directed through the liquid and onto a surface of the wafer to heat the surface for annealing. Heat dissipates from the surface of the wafer to the liquid.

According to another aspect of the invention, an apparatus for laser annealing a semiconductor wafer comprises a liquid bath adapted to receive a semiconductor wafer such that at least a portion of the wafer is immersed in liquid. A source of laser light is adapted to deliver laser light through the liquid and onto a surface of the wafer to heat the surface for annealing.

By providing a liquid in the proximity of the surface which is annealed by laser light, heat produced during annealing dissipates into the liquid. In one embodiment, a liquid is selected which has a relatively high heat capacity and a relatively high heat of vaporization, such as water. Because the heat capacity of the liquid is substantially greater than that of the surrounding materials (silicon substrate, silicon oxide, dielectric material, etc.), the liquid functions as the primary heat sink for diffusing the heat of annealing. This way, temperature variations which occur during cooling as a result of differences in heat capacities of the surrounding materials can be minimized.

### BRIEF DESCRIPTIONS OF THE DRAWINGS

The present invention will now be described in more detail with reference to embodiments of the invention, given only by way of example, and illustrated in the accompanying drawings in which:

FIG. 1A illustrates laser spike annealing of a wafer in which some poly-silicon gates are located on a surface above a silicon substrate and other poly-silicon gates are located on a surface above a silicon oxide formed by shallow trench isolation (STI).

FIG. 1B illustrates the effect of non-uniform temperatures resulting during cooling because of the higher heat capacity of the silicon substrate relative to that of silicon oxide.

FIG. 2 illustrates laser annealing a wafer which is wholly or partially immersed in water in accordance with a preferred embodiment of the invention.

FIG. 3 illustrates heat diffusion from the surface of the wafer into the water in accordance with the present invention. Heat diffuses into the water at a higher rate than it is diffused into the silicon substrate or silicon oxide. This is shown schematically by the larger arrows pointed upwardly into the water and the smaller arrows pointed downwardly into the substrate.

FIG. 4 illustrates an alternative embodiment of the present invention in which a wafer is oscillated in a stationary liquid bath while a laser source delivers laser light from beneath the liquid bath.

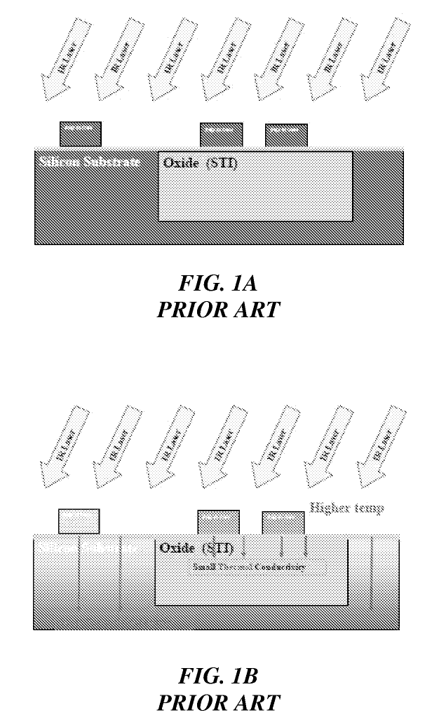

### DETAILED DESCRIPTION OF THE INVENTION

The present invention is directed to a method and apparatus for laser spike annealing of semiconductor wafers. A liquid bath functions as a heat sink for dissipating heat from the wafer following application of the laser light. The liquids have greater heat capacities than those of the underlying materials (silicon substrate, silicon oxide, metal silicide, dielectric, etc.). This way, the liquid functions as the primary heat sink for diffusing the heat of annealing. Temperature variations on the wafer surface due to heat diffusion into the underlying materials at different rates are minimized, as schematically illustrated in FIG. 3. The present invention thus has the potential to achieve more uniform temperatures during laser spike annealing, particularly during the cooling phase of the laser annealing process. This can result in the wafer surface being annealed more uniformly even when materials having diverse heat capacities are present.

Table 1 below compares the heat capacity of several common semiconductor materials with that of water. It will be apparent that water has a significantly higher heat capacity than each of the other materials.

TABLE 1

| Material | Specific Heat (J/K · g) |
|---|---|
| Si | 0.73 |
| SiO₂ | 0.7 |
| SiN | 0.71 |
| H₂O | 4.2 |

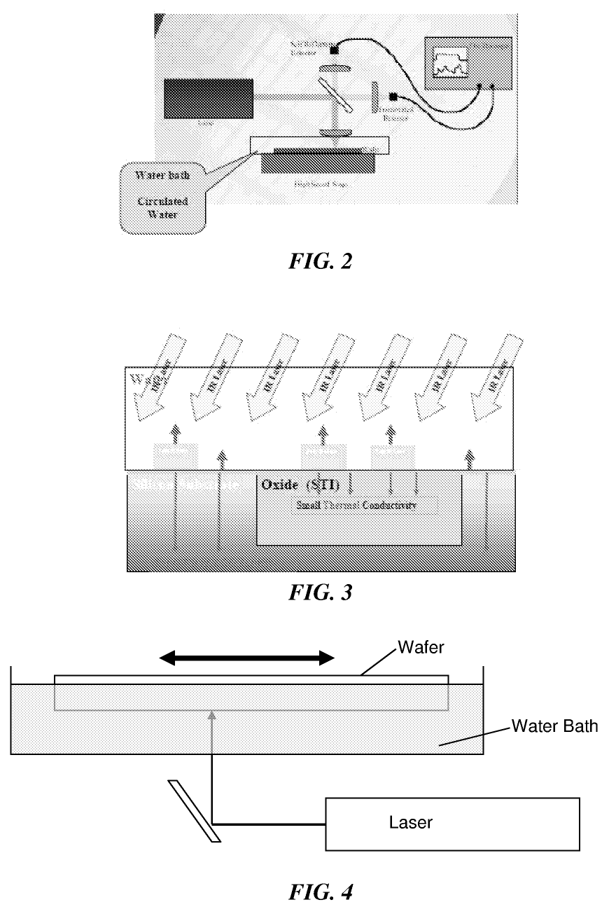

With reference to FIG. 2, a wafer can be placed in a liquid bath so that the entire wafer or a portion of the wafer is immersed in liquid. In one embodiment, at least the portions of the wafer surface which will be annealed are immersed in liquid. The liquid optionally is circulated by a fluid circulation mechanism, such as baffles, blades, or the like. Circulating the liquid helps to maintain a relatively uniform temperature distribution in the bath, which can improve the efficiency of heat transfer from the wafer to the liquid.

A source of laser light delivers laser light to the surface of the wafer to provide heat for annealing. FIG. 2 schematically illustrates a laser light source, reflector, self reflecting detector, transmitted light detector, and oscilloscope. Laser systems adapted for semiconductor wafer annealing are commercially available, e.g., from Applied Materials, Inc. (AMAT), Santa Clara, Calif., and Ultratech (San Jose, Calif.).

The wavelength of the laser light can be selected so as to avoid or minimize absorbance by the liquid. Infrared light having a wavelength greater than about 5 μm is prone to absorption by water. Most often, the wavelength of the laser light is less than 1 μm and typically ranges from about 500 to about 5000 nm, more usually from about 500 to about 1000 nm. The power of the laser typically ranges from about 1 to 2 J/cm².

The laser may be positioned so that laser light is transmitted from a location external to the liquid bath, such as from above the surface of the liquid. Alternatively, the laser may be positioned within the liquid bath so that the laser light is transmitted from below the surface of the liquid. Positioning the laser below the surface of the liquid may be desirable to avoid light refraction which can occur when the laser light is transmitted from a location external to the liquid.

Several different techniques can be used for scanning the surface of the wafer with laser light. For example, the source of laser light can be maintained relatively stationary while the wafer is oscillated so that the laser light anneals the desired surfaces of the wafer. Alternatively, the wafer can be maintained relatively stationary while the source of laser light oscillates to scan the wafer surface. Yet another alternative is to oscillate both the wafer and the source of laser light relative to each other, which potentially can yield faster scanning speeds. Any of these alternatives can be selected in combination with a laser positioned so that laser light is emitted external to the liquid bath, or one in which that laser is positioned within the liquid bath so that laser light is emitted below the surface of the liquid.

The liquid bath itself can be maintained stationary or, alternatively, can move together with the wafer. It may be desirable to maintain the liquid bath stationary, particularly when the laser light is emitted from a source external to the liquid, to avoid ripples in the water which may contribute to undesirable light refraction at the liquid surface. It is possible to maintain the liquid bath stationary while moving the wafer, for example by inverting the wafer and immersing it in a bath as illustrated in FIG. 4. The laser can be positioned to emit laser light either from a location within the liquid bath or from a location external to (e.g., below) the liquid bath. When the laser is positioned external to the liquid bath, the container used for the liquid bath should have at least one optically transparent surface to permit transmission of the laser light.

The depth of the liquid in the liquid bath can vary over a wide range but most often ranges from about 100 nm to about 15 mm, more usually from about 5 to about 10 mm. In general, the temperature of the liquid will increase to a greater extent when lower liquid depths are used upon the wafer being exposed to laser light. For example, when using a water depth of 100 nm, the temperature of the water typically increases by about 20° C. when the wafer is exposed to laser light. With a water depth of 1 mm, the water temperature typically increases by about 2° C. With a water depth of 10 mm, the water temperature typically increases by only about 0.2° C. Although even greater liquid depths may be used, excessive depths can result in undesirable thermal energy losses of the laser light.

In one embodiment, the liquid has a relatively high specific heat and does not unduly interfere with transmittance of the laser light. Water has a specific heat of 4.2 J/K·g and a heat of vaporization of 2250 J/g, and therefore functions very well as a heat sink. Infrared laser light having a wavelength of about 500 to 5000 nm can be transmitted through 10 mm of water without any appreciable energy loss. Other examples of fluids having relatively high heat capacities include monohydric alcohols, polyhydric alcohols, and the like.

Annealing temperature and annealing time can be adjusted by adjusting such parameters as laser power and scan speed, as will be apparent to persons skilled in the art. Using a laser power of 1 J/cm² and laser spot width of 200 μm, laser light can scan a silicon wafer surface at a speed of about 100 mm/sec. The laser light typically increases the temperature of the wafer surface to at least 1000° C, often about 1300° C., for an interval of several milliseconds. The surface quickly cools as heat is dissipated to the liquid and, to a lesser extent, to the underlying substrate materials.

Other embodiments of the present invention will be apparent to those skilled in the art from consideration of the specification and practice of the invention disclosed herein. It is intended that the specification and disclosed embodiments be considered as exemplary only, with a true scope and spirit of the invention being indicated by the appended claims.

What is claimed is:

1. A method of laser annealing a semiconductor wafer, the method comprising:
placing a semiconductor wafer in a liquid bath such that at least a portion of the wafer is immersed in liquid; and
directing laser light through the liquid and onto a surface of the wafer to heat the surface for annealing, whereby heat is transferred from the surface of the wafer to the liquid.

2. The method of claim 1, wherein the liquid is water.

3. The method of claim 2, wherein the depth of the water is from about 5 mm to about 15 mm.

4. The method of claim 1, wherein a source of laser light is positioned so that laser light is emitted below the surface of the liquid in the liquid bath.

5. The method of claim 1, wherein a source of laser light is positioned so that laser light is emitted above the surface of the liquid in the liquid bath.

6. The method of claim 1, wherein the wafer is kept relatively stationary and a source of laser light is moved relative to the wafer.

7. The method of claim 1, wherein a source of laser light is kept relatively stationary and the wafer is moved relative to the source of laser light.

8. The method of claim 1, wherein both the wafer and a source of laser light are moved relative to each other.

9. The method of claim 1, wherein the laser light has a power of from about 1 to about 2 J/cm².

10. The method of claim 1, wherein the laser light has a wavelength of from about 500 to about 5,000 nm.

11. A method of laser annealing a surface of a semiconductor wafer, the method comprising:
placing a semiconductor wafer in a water bath such that at least a portion of the wafer is immersed in water; and
directing laser light having a power of from about 1 to about 2 J/cm² through the water and onto a surface of the wafer to heat the surface to at least about 1000° C., whereby heat is transferred from the surface of the wafer to the water.

12. The method of claim 11, wherein a source of laser light is positioned so that laser light is emitted below the surface of the water in the water bath.

13. An apparatus for laser annealing a surface of a semiconductor wafer, the apparatus comprising:
a liquid bath adapted to receive a semiconductor wafer such that at least a portion of the wafer is immersed in liquid; and
a source of laser light adapted to deliver laser light through the liquid and onto a surface of the wafer to heat the surface for annealing.

14. The apparatus of claim 13, wherein the source of laser light is positioned so that laser light is emitted below the surface of the liquid in the liquid bath.

15. The apparatus of claim 13, wherein the source of laser light is positioned so that laser light is emitted above the surface of the liquid in the liquid bath.

16. The apparatus of claim 13, wherein the wafer is relatively stationary and the source of laser light is moveable relative to the liquid bath.

17. The apparatus of claim 13, wherein the source of laser light is relatively stationary and the wafer is moveable relative to the source laser light.

18. The apparatus of claim 13, wherein both the wafer and the laser light are moveable relative to each other.

19. The apparatus of claim 13, wherein the source of laser light has a power of from about 1 to about 2 J/cm².

20. The apparatus of claim 13, wherein the liquid bath comprises a mechanism for circulating the liquid.
